(19) United States
(12) Patent Application Publication
(10) Pub. No.: US 2026/0212093 A1
(43) Pub. Date: Jul. 23, 2026

(54) METHOD, EQUIPMENT AND MEDIUM FOR EVALUATING THE SIMULATION PERFORMANCE OF GENERAL CIRCULATION MODELS AT THE WATERSHED SCALE

(71) Applicants: Technical Centre for Soil, Agriculture and Rural Ecology and Environment, Ministry of Ecology and En, Beijing (CN); Sinochem Institute of Innovation & Technology (Beijing) Co., Ltd., Beijing (CN); Shandong Academy for Environmental Planning, Jinan (CN)

(72) Inventors: Tiezhu YAN, Beijing (CN); Huading SHI, Beijing (CN); Xiaoxia YU, Beijing (CN); Ying FENG, Beijing (CN); Pengli XUE, Beijing (CN); Chuanxing ZHANG, Beijing (CN); Li MO, Beijing (CN)

(21) Appl. No.: 19/450,668

(22) Filed: Jan. 15, 2026

(30) Foreign Application Priority Data
Jan. 17, 2025 (CN) 202510072174.7

(51) Int. Cl. G06F 30/28

(52) U.S. Cl. CPC G06F 30/28

(57) ABSTRACT

The present application discloses a method, equipment and medium for evaluating the simulation performance of General Circulation Models (GCMs) at the watershed scale. This method includes the following steps: first, obtaining a first subset of GCMs by evaluating the simulation performance of GCMs on a global scale based on the ground meteorological variable observation data and their corresponding simulation data from each GCM, under predefined evaluation criteria; second, obtaining a second subset of GCMs by evaluating the simulation performance of each GCM in the first subset at a regional scale against observation data of large-scale atmospheric variables and their corresponding simulation data; and finally, evaluating the simulation performance of each GCM in the second subset at a watershed scale against observation data of ground meteorological variables from ground meteorological stations and the corresponding simulation data.

### CROSS-REFERENCE TO RELATED APPLICATIONS

The present application claims priority to Chinese patent application No. 202510072174.7, filed on Jan. 17, 2025, the entire contents of which are incorporated herein by reference.

### TECHNICAL FIELD

The present application relates to the technical field of GCMs' simulation performance evaluation for watershed future climate change impacts research, and particularly to a method, equipment and medium for evaluating the simulation performance of GCMs at the watershed scale.

### TECHNICAL BACKGROUND

Currently, General Circulation Models (GCMs) are effective tools for global climate simulations and climate change assessments, and are now widely used in the field of watershed future climate change impact research. However, different GCMs vary in their model mechanisms, initial conditions, spatial resolution, and parameterization schemes and so on, this resulting in significant variations in the accuracy of their output results at the watershed scale. Despite the continuous improvement in the simulation accuracy of ground temperature and precipitation from GCMs in different regions, it remains the greatest uncertainty in research result of future climate change impact. It is generally recognized that the agreement of the results from historical simulation results of GCMs with concurrent observations is the only feasible way to measure the applicability of GCMs to future climate change impact research at the watershed scale. Therefore, choosing GCMs that accurately represents watershed climate characteristics to generate future climate change scenarios has become an important means to increase the result confidence in future climate change impact research.

In the watershed climate change impact studies, conventional evaluation methods of GCMs' simulation performance mainly conduct the simulation performance evaluation of mean state of ground meteorological variables (such as precipitation, temperature, etc.) for some subjectively selected GCMs, and these methods often ignore the simulation performance of large-scale atmospheric variables that affect ground meteorological variables and the dynamic simulation performance evaluation of ground meteorological variables. Thus, existing GCMs simulation performance evaluations struggle to provide a comprehensive, scientific and systematic assessment of GCMs' simulation performance at the watershed scale, which may leads to a decrease in the results credibility of climate change impact research.

### SUMMARY

The present application aims to provide a method, equipment and medium for evaluating the simulation performance of GCMs at the watershed scale, achieving a progressive and systematic evaluation of GCM simulation performance.

The present application provides the following scheme to achieve the above aim.

In the first aspect, the present application provides a method for evaluating the simulation performance of GCMs at the watershed scale, including the following several steps.

Obtaining observation data and corresponding GCMs' simulation data; when the above-mentioned observation data are ground meteorological variable observation data, the corresponding GCMs' simulation data are ground meteorological variable simulation data from each GCM; When the observed data are large-scale atmospheric variables observation data, the corresponding GCMs' simulation data are large-scale atmospheric variables simulation data from each GCM.

Taking the mean state as the evaluation criterion, the first subset of GCMs is obtained by evaluating the simulation performance of each GCM on a global scale based on observation data of ground meteological variables from ground meteorological stations and the corresponding simulation data from each GCM, wherein the simulation performance of each GCM in the first subset satisfies a first present performance condition.

Taking the mean state and correlation as evaluation criteria, the second subset of GCMs is obtained by evaluating the simulation performance of each GCM in the first subset at a regional scale based on observation data of the large-scale atmospheric variables and the corresponding simulation data from each GCM, wherein the simulation performance of each GCM in the second subset satisfies a second preset performance condition.

Taking mean state, change trend, correlation, and probability distribution as evaluation criteria, simulation performance of each GCM in the second subset at a watershed scale is evaluated based on observation data of ground meteorological variables from ground meteorological stations and the corresponding simulation data from each GCM.

In the second aspect, the present application provides a computer equipment, including: a memory, a processor and a computer program stored on the memory and capable of running on the processor. The processor executes the computer program for the evaluation of GCMs' simulation performance at the watershed scale.

In the third aspect, the present application provides a computer-readable storage medium in which a computer program is stored. The computer program is executed by the processor for the evaluation of GCMs' simulation performance at the watershed scale.

Based on the exemplary embodiments provided by the present application, the following technical effects are achieved: the present application provides a method, equipment and medium for the performance evaluation of GCMs' simulation at the watershed scale, which is applicable to watershed climate change impact research. Through the stepwise screening of the first subset of GCM, the second subset of GCM, and the third subset of GCM, progressive evaluation of all GCMs' simulation performance is achieved, and the number of GCMs to be evaluated is gradually reduced to avoid the problem of large amounts of data processing when all GCMs are selected. Furthermore, by screening through the three subsets of models, a more detailed and in-depth evaluation of the superior GCMs can be achieved with higher accuracy, avoiding the bias in simulation performance evaluation that arises from subjective selection of GCMs. In this application, large-scale atmospheric variables, which affect surface meteorological variables, are considered in the evaluation of GCMs' simulation performance, thereby enhancing the reliability of simulation data of surface meteorological variables. At the same time, four criteria, including mean state, change trend, correlation, and probability distribution, are chosen as evaluation criteria, which can ensure the robustness of the final GCM simulation performance evaluation results, help to reduce uncertainties in constructing future climate scenarios at the watershed scale, and increase the confidence in research findings regarding watershed future climate change impact.

In summary, this application is suitable for watershed climate change impact research. It can enables a comprehensive, scientific, and reasonable evaluation of GCM simulation performance at the watershed scale and thus reduce uncertainties in simulation results related to watershed climate change impacts. This is crucial for improving the confidence in the research results of watershed climate change impact.

### BRIEF DESCRIPTIONS OF THE DRAWINGS

To illustrate the technical solutions in the exemplary embodiments of this application or in the prior art more clearly, the drawings required for describing the exemplary embodiments are briefly introduced below. Obviously, the drawings described below represent only some exemplary embodiments of this application. For a person of ordinary skill in the art, other drawings may also be derived from these drawings without creative effort.

FIG. 1 shows an application environment diagram of the method for evaluating GCMs' simulation performance by an exemplary embodiment of the present application.

FIG. 2 is a flow diagram of the method for evaluating GCMs' simulation performance provided by an exemplary embodiment of the present application.

FIG. 3 is a schematic diagram of the structure of a computer equipment provided by an exemplary embodiment of the present application.

### DETAILED DESCRIPTIONS OF EMBODIMENTS

The technical solution in the exemplary embodiments of the present application is described clearly and completely with the attached picture in the exemplary embodiments of the present application. Apparently, the exemplary embodiments described are only part of the present application, not all of them. All other exemplary embodiments obtained by a person of ordinary skill in the field without creative effort shall fall within the scope of protection of this application.

This application is applicable to the evaluation of the of GCMs' simulation performance for the watershed climate change impact research. Its primary objective is to reduce the uncertainty in watershed climate change impact research, thus improve the credibility of the research findings.

To make the above-mentioned objective, features and advantages of the present application more obvious and understandable, a further detailed description of the present application is provided below with the attached picture and specific implementation mode.

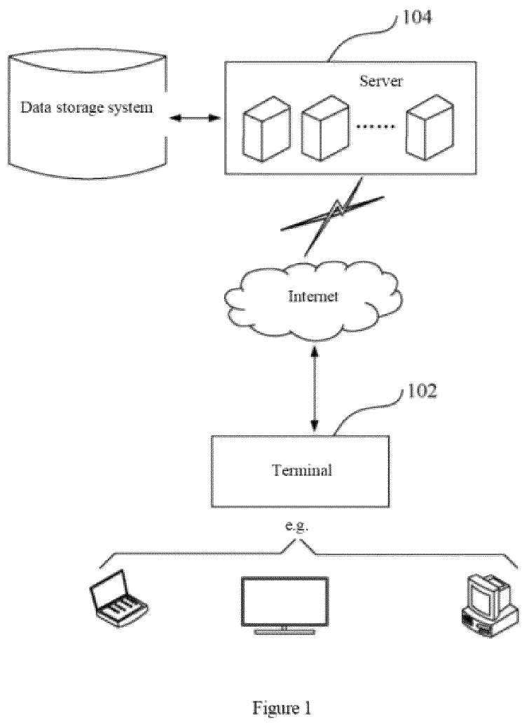

The evaluation method of GCMs' simulation performance, applicable to the watershed climate change impact research as provided by the exemplary the embodiments of this application, can be applied to the application environment as shown in FIG. 1. Thereinto, terminal 102 communicates with server 104 via the network. The data storage system can store the data that server 104 needs to be processed. Data storage systems can be set up separately, integrated into server 104, or placed in the cloud or on other servers. Terminal 102 can send observation data and the corresponding simulation data from GCMs to Server 104. After receiving the data, server 104 will evaluate the simulation performance of each GCM on a global scale using the mean state as the evaluation criterion, based on ground meteorological variable observation data and the corresponding simulation data from each GCM, thereby obtaining the first subset of GCMs; Using the mean state and correlation as evaluation criteria, evaluate the simulation performance of each GCM in the first subset on a regional scale based on the observation data of large-scale atmospheric variables and the corresponding simulation data of each GCM, in order to obtain the second subset of GCMs; Using the mean state, change trend, correlation, and probability distribution as evaluation criteria, evaluate the simulation performance of each GCM in the second subset on a watershed scale based on the surface meteorological variables observationa data and the corresponding simulation data from each GCM. Server 104 can feed back the evaluation results of the simulation performance of each GCM to terminal 102. In addition, in some exemplary embodiments, the evaluation method of GCMs' simulation performance at the watershed scale can also be implemented separately by server 104 or terminal 102.

Thereinto, terminal 102 may include, but is not limited to, various desktop computers, laptops, tablets and Internet of Things devices. Server 104 can operate as a standalone server, a cluster of multiple servers, or a cloud server.

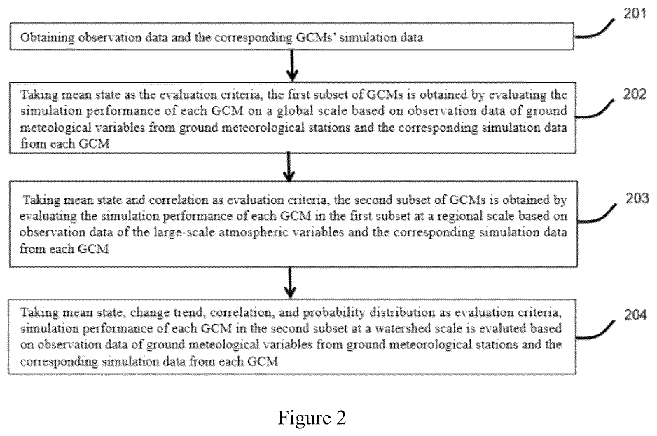

In an exemplary embodiment, an evaluation method of GCMs' simulation performance is provided as shown in FIG. 2. This method is executed by computer equipment, which may specifically be carried out solely by terminals, servers, or other computer equipments, or jointly by terminals and servers. In an exemplary embodiment of this application, the method is illustrated by taking its application by server 104 in FIG. 1 as an example, including steps 201 to 204 below.

Step 201: Obtaining observation data and the corresponding GCMs' simulation data; When the above-mentioned observation data are ground meteorological variable observation data, the corresponding GCMs' simulation data are the simulation data of ground meteorological variables from each GCM; When the above-mentioned observation data are large-scale atmospheric variables observation data, the corresponding GCM simulation data are the simulation data of large-scale atmospheric variables from each GCM;

In an exemplary embodiment of the present application, the process of acquiring the observation data and corresponding simulation data from GCMs includes the following steps (11) to (13), specifically involving the identification of the spatial range for GCMs simulation performance evaluation, data collection and preprocessing.

(11) Obtaining initial observation data of ground meteorological variables from multiple ground meteorological stations; Obtaining large-scale atmospheric variables data from the global NCEP reanalysis dataset as initial observation data of large-scale atmospheric variables. Obtaining initial simulation data of ground meteorological variables and large-scale atmospheric variables from each GCM during the same period of the initial large-scale atmospheric variables observation data.

Specifically, before obtaining the initial data, or after obtaining the initial data, it is necessary to determine the evaluation range that may be used in steps 202-204. This application involves three evaluation scales: global scale, regional scale and watershed scale. Thereinto, the spatial range at the regional scale must objectively reflect regional atmospheric physical processes and characterize the spatiotemporal change characteristics of regional surface meteorological variables. For example, when conducting climate change impact research within a watershed in the North China Plain, the North China Plain itself can be selected as the regional scale. If the watershed area occupies only a few GCMs grids, the performance evaluation of GCMs' ground meteorological variable simulation can be carried out at the regional scale.

Data collection includes annual/monthly time-scale precipitation and average temperature data from surface meteorological stations within the evaluation range, which can serve as the initial surface meteorological variable observation data. Data collection also involves the collection of large-scale atmospheric variables data from the NCEP reanalysis dataset at the year/month time scale, which can be used as initial large-scale atmospheric variables observation data. Additionally, data collection includes annual/monthly time-scale simulation data of surface precipitation, average temperature, and large-scale atmospheric variables from GCMs, with the same period of the corresponding surface observation data. Thereinto, the length of time series of the above-mentioned data is generally no less than 30 years.

(12) Applying bilinear interpolation to match the spatial resolution of the initial ground meteorological variable simulation data to that of the initial ground meteorological variable observation data; applying bilinear interpolation to match the spatial resolution of the initial large-scale atmospheric variables simulation data to that of the initial large-scale atmospheric variables observation data.

The spatial resolution of different datasets can be unified through the above-mentioned bilinear interpolation method. In a practical application, when the evaluation of the GCMs' simulation performance for ground meteorological variable in step 202 or step 204 is conducted, the spatial resolution of the simulation data of ground meteorological variables from GCMs collected in step (11) can be matched to the longitude and latitude of the ground meteorological stations by means of the bilinear interpolation method, thereby achieving a match of spatial resolution. When the evaluation of the GCMs' simulation performance for large-scale atmospheric variables in step 203 is conducted, the bilinear interpolation method can be used to match the spatial resolution of simulation data of large-scale atmospheric variables from GCMs with the corresponding observation data from the NCEP reanalysis dataset.

(13) For observation data of the initial surface meteorological variables and large-scale atmospheric variables after the process of spatial resolution unification, arithmetic averaging or spatial interpolation is applied to obtain the final observation data; Similarly, for simulation data of the initial surface meteorological variables and large-scale atmospheric variables after the process of spatial resolution unification, arithmetic averaging or spatial interpolation is applied to derive the simulation data for the GCMs. The annual or monthly observation data and the corresponding simulation data from the GCM are the average of be the average of surface meteorological variables or large-scale atmospheric variables at the global scale, regional scale or watershed scale.

In step 202, taking the mean state as an evaluation criteria, the first subset of GCMs is obtained by evaluating the simulation performance of each GCM on a global scale based on observation data of ground meteorological variables from ground meteorological stations and the corresponding simulation data from each GCM, wherein the simulation performance of each GCM in the first subset satisfies a first preset performance condition.

Specifically, the simulation accuracy of the mean state of the climate system on a global scale is a necessary condition for the successful application of GCMs in climate change impact researches. The evaluation of simulation performance is conducted by assessing the match degree of the mean state between the observation data of surface meteorological variables and the corresponding that of simulation data from GCMs. After the simulation performance evaluation, some GCMs with poor simulation performance (i.e., not meeting the first preset performance condition, such as the overall score of the GCMs being less than the first preset value) can be excluded from the evaluation process of GCMs' simulation performance. That is to say, this part of the GCMs completes the simulation performance evaluation. The remaining GCMs form the first subset of GCMs, which are then used for the evaluation of GCMs' simulation performance on the large-scale atmospheric variables in step 203.

In step 203, Taking the mean state and correlation as evaluation criterias, the second subset of GCMs is obtained by evaluating the simulation performance of each GCM in the first subset at a regional scale based on observation data of the large-scale atmospheric variables and the corresponding simulation data from each GCM, wherein the simulation performance of each GCM in the second subset satisfies a second preset performance condition.

Specifically, in the climate change impact research on watershed hydrology and water environment, surface precipitation and temperature are often chosen as meteorological variables to characterize climate change. In terms of atmospheric physical processes, GCMs can realistically simulate the physical processes of the climate system, and their simulation accuracy of surface precipitation and temperature is affected by the simulation accuracy of large-scale atmospheric variables. Therefore, high simulation accuracy of large-scale atmospheric variables, which are directly related to temperature and surface precipitation and influence the simulation performance of temperature and surface precipitation, is a prerequisite for achieving effective simulation of temperature and precipitation at the regional scale in GCMs. Consequently, in this step, large-scale atmospheric variables that are significantly correlated with surface precipitation and temperature are selected as the target variables to be evaluated.

The evaluation of simulation performance is conducted by assessing the match degree of the mean state and annual distribution between simulation data of the large-scale atmospheric variables from GCMs and the corresponding that of observation data from NCEP. After the simulation performance evaluation, some GCMs with poor simulation performance of large-scale atmospheric variables (i.e., not meeting the second preset performance condition, such as the overall score of the GCMs being less than the second preset value) can be excluded from the evaluation process of simulation performance, and the remaining GCMs will be used as the second subset of GCMs for the comprehensive evaluation of the simulation performance of the ground meteorological variables in step 204.

The above-mentioned steps 202 and 203 implement a progressive screening process according to the evaluation of GCMs' simulation performance, which gradually eliminates GCMs with poor simulation performance according to certain logic, and finally screens out the set of GCMs suitable for comprehensive evaluation of GCMs' simulation performance of ground meteorological variables at the watershed scale. This progressive processing follows two basic logics: (1) In terms of spatial scale, good simulation performance for the mean climate state at large scales (e.g., the global scale) is a prerequisite for achieving accurate simulation for surface meteorological variables by GCMs at the watershed scale; (2) In terms of physical processes, good simulation performance for large-scale atmospheric variables, which are significantly correlated with and physically meaningful for surface meteorological variables, is a prerequisite for achieving effective simulation for surface meteorological variables by GCMs at the watershed scale.

In step 204, taking the mean state, change trend, correlation, and probability distribution as evaluation criteria, the evaluation of the simulation performance of each GCM in the second subset on a watershed scale is conducted based on the observation data of surface meteorological variables and the corresponding simulation data from each GCM.

In an exemplary embodiment of the present application, the mean state is used to characterize the match degree of the statistical indexes related to the mean state between observation data and the corresponding simulation data from GCMs within a first preset time scale. The corresponding evaluation indexes include mean, standard deviation and root mean square error.

The trend of change is used to characterize the match degree of the trend change and its trend magnitude between observation data and the corresponding simulation data from GCMs within a second preset time scale; The corresponding evaluation indexes include the rank statistic (Z value) and the change magnitude (Slope value), both of which are derived based on the non-parametric Mann-Kendall trend test method.

The correlation is used to characterize the match degree of temporal and spatial distribution variations between the observation data and simulation data from GCMs within a third preset time scale; The corresponding evaluation indexes include the intra-annual distribution correlation coefficient and annual-scale spatial correlation coefficient.

The probability distribution is used to characterize the match degree of probability distribution between the observation data and the corresponding simulation data from GCMs within the fourth preset time scale; The corresponding indexes include KL divergence, Significance score, and Bier Score.

The first, second, third and fourth preset time scales mentioned in the above four evaluation criteria may all be set to the annual scale, or they can be adjusted by relevant technical personnel as needed. The evaluation indexes corresponding to the above-mentioned four evaluation criteria can be divided into two types: one type of evaluation index only describes the statistical characteristics of the GCMs simulation values, such as mean, standard deviation, rank statistics, and change magnitude; The other type describes the match degree between simulation data from GCMs and observation data, such as root mean square error, intra-annual distribution correlation coefficient, annual-scale spatial correlation coefficient, Sscore value, BS value, KL divergence, etc. The indexes corresponding to the above four evaluation criteria can be shown in Table 1 below.

TABLE 1

| Target | Evaluation | |
|---|---|---|
| Layer | Criteria | Evaluation index |
| simulation | mean state | mean, standard deviation, root mean |
| performance | | square error, |
| evaluation | change trend | rank statistic (Z-value), change |
| | | magnitude (Slope value) |
| | correlation | Intra-annual distribution correlation |
| | | coefficient, annual scale spatial |
| | | correlation coefficient |
| | probability | Kullback-Leibler divergence (KL |
| | distribution | Divergence), Sscore value, BS value |

In another exemplary embodiment of the present application, the process of simulation performance evaluation of each GCM includes the following steps (21)-steps (25).

(21) Based on the evaluation criteria, determine the corresponding multiple evaluation indexes. As mentioned in step 202, the corresponding multiple evaluation indexes include mean, standard deviation, root mean square error; In step 203, the corresponding multiple evaluation indexes include mean, standard deviation, root mean square error, intra-annual distribution correlation coefficient, and annual scale spatial correlation coefficient; In step 204, the corresponding multiple indexes include mean, standard deviation, root mean square error, rank statistic, change magnitude, intra-annual distribution correlation coefficient, annual scale spatial correlation coefficient, KL divergence, Sscore value, BS value.

(22) For any GCM, the score of each evaluation index are calculated at the global, regional, or watershed scales according to the corresponding observation data and simulation data from GCMs; Since the data for each quantitative evaluation index with different units and dimension are not compared directly, thus all evaluation indexes need to be standardized. This application adopts the extreme value processing method to standardize the original data of the evaluation indexes and assign 0 to 10 points to the results of the evaluation indexes that measure the GCMs' simulation performance. Specifically, the calculation formula of the score for each evaluation index is:

$${x}_{i j}^{′} = \{ \begin{matrix}\frac{{x}_{ij} - {( {x}_{i} )}_{min}}{{( {x}_{i} )}_{max} - {( {x}_{i} )}_{min}} \times 10 ; & when {X}_{ij} is a positive indicator \\ \frac{{( {x}_{i} )}_{max} - {x}_{ij}}{{( {x}_{i} )}_{max} - {( {x}_{i} )}_{min}} \times 10 ; & when {X}_{ij} is a negative indicator\end{matrix}$$

where x′ij is the score of the i-th evaluation index for the j-th GCM, xij is the value of the i-th evaluation index for the j-th GCM, which can be the statistical value of the i-th evaluation index or the relative error of the i-th evaluation index from the observed value, and which type it belongs to depends on the type of the evaluation index; (xi) min and (xi) max are the minimum and maximum values of the i-th evaluation index for all GCMs, respectively.

(23) The analytic hierarchy process method is adopted to calculate the subjective weights of each evaluation index; the entropy weight method is used to calculate the objective weights of each evaluation index. Specifically, due to the fact that subjective weights are greatly influenced by human factors and may cause the deviations in the calculation results, objective weight is introduced to correct and compensate for the above-mentioned limitations.

The main calculation steps for the weights of each evaluation index using the analytic hierarchy process method are as follows: Construct the judgment matrix

A=(ail)n×n, then normalize the judgment matrix by column to obtain the normalized matrix āil, then add the elements of the same row in the normalized matrix ail to obtain the vector \tilde{w}i, then divide this result by the number of evaluation indexes, and finally obtaining the weights of the specific evaluation indexes. The calculation formula is as follows:

$${\overline{a}}_{i 1} = {a}_{i 1} / {\sum }_{l = 1}^{n} {a}_{i 1} , l = 1 , 2 , … , n ∘$$

$${\tilde{w}}_{i} = {\sum }_{i = 1}^{n} {\overline{a}}_{i 1} , i = 1 , 2 , … , n ∘$$

$${zw}_{i} = {\tilde{w}}_{i} / n ∘$$

where ail is the importance of the i-th evaluation metric relative to the 1-th evaluation metric; zwi is the subjective weight of the i-th evaluation metric; n is the number of evaluation index.

The entropy weight method is used to calculate the objective weights of each evaluation index, with the following steps:

$${P}_{ij} = \frac{{x}_{ij}}{{\sum }_{j = 1}^{s} {x}_{ij}} ∘$$

$${E}_{i} = - \frac{1}{ln ( s )} {\sum }_{j = 1}^{s} {P}_{ij} \cdot ln {P}_{ij} ∘$$

$${kw}_{i} = \frac{1 - {E}_{1}}{n - {\sum }_{i = 11}^{n} {E}_{1}} ∘$$

where xij represents the value of the i-th evaluation index of the j-th GCM; Pij represents the feature weight of the j-th GCM under the i-th evaluation index, and Ei represents the entropy of the i-th evaluation index; kwi represents the objective weight of the i-th evaluation metric, s represents the number of GCMs.

(24) Determine the corresponding combination weight of each evaluation index based on its subjective weight and objective weight, and the calculation formula is as follows:

$${W}_{i} = α \cdot {zw}_{i} + β \cdot {kw}_{i} ;$$

where Wi represents the combination weight of the i-th evaluation metric; α and β represent the relative importance of subjective weight and objective weight, respectively; α+β=1; 0≤α≤1; 0≤β≥1. In one specific application, the values of α and β can be taken as 0.5.

(25) The overall score of the GCM is calculated based on the combination weights of all the evaluation indexes and their evaluation scores, and marked as the simulation performance value.

In a practical application, for a single evaluation variable (i.e., when the observation data only involves a single evaluation variable), such as surface meteorological variable (temperature) or the large-scale atmospheric variables (relative humidity at 500 hpa), the following formula is used to calculate the score Y for each GCM:

$$Y = {\sum }_{i = 1}^{n} {W}_{i} {x}_{i} ∘$$

where xi represents the score of the i-th evaluation index, Wi represents the combination weight of the i-th evaluation index;
When the evaluation variables are multivariate (i.e., when the observed data involve multiple evaluation variables), for example, there are precipitation and temperature observation data of surface meteorological variables, or there are multiple large-scale atmospheric variables, the following formula is used to calculate the overall score S for each GCM:

$$S = {\sum }_{h = 1}^{m} {Y}_{h} {γ}_{h} ∘$$

Where, Yh represents the score corresponding to the simulation performance of the h-th evaluation variable in the GCM; γh represents the weight of the h-th evaluation variable, determined by the method described in step (23); m represents the number of evaluation variables, when the evaluated ground meteorological variables are precipitation and temperature, m equals 2.

In summary, the present application conducts the progressive evaluation of GCMs's simulation performance at the global or regional scales, and further implements the comprehensive evaluation of GCMs' simulation performance at the watershed scale. Specifically, the values of evaluation indexes are calculated based on observation data of surface and large-scale atmospheric variables along with the corresponding simulation values from various GCMs, and the dataset of evaluation indexes is constructed, these processes finally determine the overall score of each GCM. This application provides a comprehensive, scientific and systematic assessment of GCMs' simulation performance involved in the field of watershed future climate change impact research.

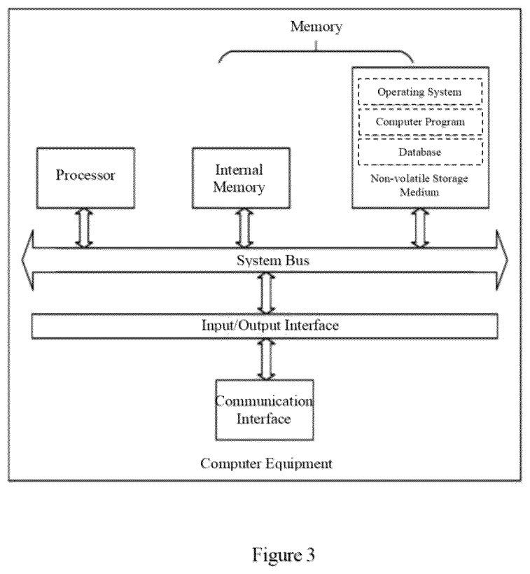

In an exemplary embodiment, a computer equipment is provided, which can be a server or a terminal, and its internal structure diagram can be as shown in FIG. 3. The computer equipment includes a processor, a memory, an input/output interface (Input/Output, abbreviated as I/O), and a communication interface. The processor, the memory, and the input/output interface are connected through a system bus, and the communication interface is connected to the system bus through the input/output interface. The processor of the computer equipment is used to provide computing and control capabilities. The memory of the computer equipment includes a non-volatile storage medium and an internal memory. The non-volatile storage medium stores an operating system, a computer program, and a database. The internal memory provides an operation environment for the operating system and the computer programs stored in the non-volatile storage medium. The input/output interface of the computer equipment is used for information exchange between the processor and external equipment. The communication interface of the computer equipment is used to communicate with external terminals through a network. When the computer program is executed by the processor, it implements the evaluation method of GCMs' simulation performance.

It can be understood by those skilled in the art that the structure shown in FIG. 3 is merely a block diagram representing the parts relevant to the solution of this application and does not constitute a limitation of the computer equipment to which the present application scheme is applied. The specific computer equipment may include more or fewer components than shown in the figure, or combine certain components, or have a different component layout.

In an exemplary embodiment, a computer equipment is provided, including a memory and a processor in which a computer program is stored, and the processor implements the steps in the embodiments of the above-mentioned methods when executing the computer program.

In an exemplary embodiment, a computer-readable storage medium is provided, storing a computer program which implements the steps in the embodiments of the above-mentioned methods when executed by a processor.

In an exemplary embodiment, a computer program product is provided, including a computer program which implements the steps in the embodiments of the above-mentioned methods when executed by a processor.

It should be noted that the user information (including but not limited to user device information, user personal information, etc.) and data (including but not limited to data for analysis, storage, display, etc.) involved in the present application are authorized by the user or fully authorized by relevant parties, and the collection, use and processing of related data comply with relevant regulations.

It should be understood by those skilled in the art that the implementation of all or part of the processes in the exemplary embodiments can be accomplished by relevant hardware under the execution of a computer program. The computer program may be stored in a non-volatile computer-readable storage medium. When executed, the computer program may include the procedures described in the exemplary embodiments of the above-mentioned methods. Any memory, database or other medium mentioned in the exemplary embodiments provided by the present application may include at least one of non-volatile and volatile memory. Non-volatile memory may include read-only memory (ROM), magnetic tape, floppy disk, flash memory, optical memory, high-density embedded non-volatile memory (ReRAM), magnetoresistive random access memory (MRAM), ferroelectric random access memory (FRAM), phase change memory (PCM), graphene memory, etc. Volatile Memory can include random access memory (RAM) or external high-speed cache memory, etc. As an illustration rather than a limitation, RAM can take various forms, such as static random access memory (SRAM) or dynamic random access memory (DRAM), etc.

The databases involved in the exemplary embodiments provided in the present application may include at least one of relational databases and non-relational databases. Non-relational databases may include but are not limited to blockchain-based distributed databases, etc. The processors involve in the embodiments provided in the present application may include but are not limited to general-purpose processors, central processing units, graphics processing units, digital signal processors, programmable logic devices, or quantum computing-based data processing logic devices, etc.

The technical features of the above exemplary embodiments can be combined in any way. For the sake of conciseness, not all possible combinations of the technical features of the above exemplary embodiments are described. However, as long as there is no contradiction in the combination of these technical features, they should be considered within the scope of the present specification.

The principles and implementation methods of this application are illustrated through specific examples in this document. The descriptions of the above examples are only intended to help understand the methods and core ideas of this application. At the same time, those skilled in the art may make changes in specific implementation methods and application scopes based on the ideas of this application. In conclusion, the content of this specification should not be construed as a limitation of this application.

What is claimed is:

1. A method for evaluating the simulation performance of GCMs at the watershed scale, is characterized by comprising the following steps:
Obtaining observation data and the corresponding GCMs' simulation data; When the observation data are ground meteorological variable observation data, the corresponding GCMs' simulation data are the simulation data of ground meteorological variable from each GCM; When the observation data are large-scale atmospheric variables observation data, the corresponding GCM simulation data are the simulation data of large-scale atmospheric variables from each GCM;
Taking the mean state as the evaluation criteria, the first subset of GCMs is obtained by evaluating the simulation performance of each GCM on a global scale based on observation data of ground meteorological variables from ground meteorological stations and the corresponding simulation data from each GCM, wherein the simulation performance of each GCM in the first subset satisfies a first preset performance condition;
Taking the mean state and correlation as evaluation criteria, the second subset of GCMs is obtained by evaluating the simulation performance of each GCM in the first subset at a regional scale based on observation data of the large-scale atmospheric variables and the corresponding simulation data from each GCM, wherein the simulation performance of each GCM in the second subset satisfies a second preset performance condition;
Taking the mean state, change trend, correlation, and probability distribution as evaluation criteria, simulation performance of each GCM in the second subset at a watershed scale is evaluated based on observation data of ground meteorological variables from ground meteorological stations and the corresponding simulation data from each GCM;
The mean state is used to characterize the match degree between the GCMs' simulation data and the corresponding observation data in terms of average statistical characteristics in the first preset time scale; The trend change is used to characterize the match degree of trend change and its trend magnitude between the GCMs' simulated data and the corresponding observation data in the second preset time scale; The correlation is used to characterize the match degree between the temporal and spatial distribution changes in the GCMs' simulation data and the corresponding observation data in a third preset time scale; The probability distribution is used to characterize the match degree between the GCMs' simulation data and the corresponding observation data in the fourth preset time scale.

2. According to claim 1, the evaluation method of GCMs' simulation performance at the watershed scale is characterized in that the evaluation process of GCMs' simulation performance includes:
According to the evaluation criteria, determining the corresponding multiple evaluation indexes;
For any GCM, calculating a score for each evaluation index at the global, regional, or watershed scales based on the corresponding observation data and the simulation data from that GCM;
Using the analytic hierarchy process method (AHP) to calculate the subjective weights of each evaluation index; using the entropy weight method to calculate the objective weights of each evaluation index;
Determining the combination weight for each evaluation index based on its subjective weight and objective weight;
Calculating the overall score of the GCM based on the combination weights of all the evaluation indexes and their evaluation scores, and designating this overall score as the evaluation value of its simulation performance.

3. According to claim 2, the evaluation method of the GCM's simulation performance at the watershed scale is characterized in that: when the evaluation criteria is the mean state, the corresponding evaluation index includes the mean, standard deviation and root mean square error; when the evaluation criteria is the change trend, the corresponding evaluation indexes include rank statistics and change range; when the evaluation criteria is correlation, the corresponding evaluation indexes include the intra-annual distribution correlation coefficient for the evaluation variables and annual-scale spatial correlation coefficient for the evaluation variables; when the evaluation criterion is the probability distribution, the corresponding evaluation indexes include KL divergence, Sscore value, and BS value.

4. According to claim 2, the evaluation method of the GCM's simulation performance at the watershed scale is characterized in that the calculation formula for the evaluation scores for each evaluation index is as follows:
$${x}_{i j}^{′} = \{ \begin{matrix}\frac{{x}_{ij} - {( {x}_{i} )}_{min}}{{( {x}_{i} )}_{max} - {( {x}_{i} )}_{min}} \times 10 ; & when {X}_{ij} is a positive indicator \\ \frac{{( {x}_{i} )}_{max} - {x}_{ij}}{{( {x}_{i} )}_{max} - {( {x}_{i} )}_{min}} \times 10 ; & when {X}_{ij} is a negative indicator\end{matrix}$$
where x′ij is the score of the i-th evaluation index for the j-th GCM, xij is the value of the i-th evaluation index for the j-th GCM, and (xi) min and (xi) max are the minimum and maximum values of the i-th evaluation index for all GCM, respectively.

5. According to claim 2, the evaluation method of the GCM's simulation performance at the watershed scale is characterized by the use of the analytic hierarchy process method to calculate the subjective weight of each evaluation index. The calculation steps are as below:
Constructing the judgment matrix A=(ail)n×n, then normalize the judgment matrix by column to obtain the normalized matrix āᵢₗ, adding the elements of the same row in the normalized matrix āᵢₗ obtain the vector \tilde{w}ᵢ, dividing by the number of evaluation indexes, and finally obtaining the weights of the specific evaluation indexes, the calculation formula is as follows:
$${\overline{a}}_{i 1} = {a}_{i 1} / {\sum }_{l = 1}^{n} {a}_{i 1} , il = 1 , 2 , … , n ;$$
$${\tilde{w}}_{i} = {\sum }_{i = 1}^{n} {\overline{a}}_{i 1} , i = 1 , 2 , … , n ;$$
$${zw}_{i} = {\tilde{w}}_{i} / n ;$$
where ail is the importance of the i-th evaluation metric relative to the l-th evaluation metric; zwi is the subjective weight of the i-th evaluation metric;
Entropy weight method is adopted to calculate the objective weights of each evaluation metric, with the following steps:
$${P}_{ij} = \frac{{x}_{ij}}{{\sum }_{j = 1}^{s} {x}_{ij}} ;$$
$${E}_{i} = - \frac{1}{ln ( s )} {\sum }_{j = 1}^{s} {P}_{ij} \cdot ln {P}_{ij} ;$$
$${kw}_{i} = \frac{1 - {E}_{1}}{n - {\sum }_{i = 11}^{n} {E}_{1}} ;$$
where xij represents the value of the i-th evaluation index of the j-th GCM; Pij represents the feature weight of the j-th GCM under the i-th evaluation index, and Ei represents the entropy of the i-th evaluation index; kwi represents the objective weight of the i-th evaluation metric, and s represents the number of GCMs;
The formula for calculating the combination weight is as follows:
Wᵢ=α·zwᵢ+B·kwᵢ;
where Wi represents the combination weight of the i-th evaluation metric; α and β represent the relative importance of subjective weight and objective weight, respectively, with α+β=1.

6. According to claim 2, the evaluation method of the GCM's simulation performance at the watershed scale is characterized in that the overall score of the GCMs is calculated based on the combination weight and evaluation scores of all the evaluation index, as follows:
When the observation data is a single evaluation variable, the score Y of the GCM for that variable is calculated using the following formula:
$$Y = {\sum }_{i = 1}^{n} {W}_{i} {x}_{i}$$
where xi represents the score of the i-th evaluation index, and Wi represents the combination weight of the i-th evaluation index;
When the observation data consists of multiple evaluation variables, the overall score S of the GCM is calculated using the following formula:
$$S = {\sum }_{h = 1}^{m} {Y}_{h} {γ}_{h}$$
where Yh represents the score of the GCM corresponding to the h-th evaluation variable; γₕ represents the weight of the h-th evaluation variable; and m represents the number of evaluation variables.

7. According to claim 1, the evaluation method of the GCMs' simulation performance at the watershed scale is characterized in that the process of obtaining the observation data and the corresponding GCMs' simulation data, including the following steps:
Obtaining initial observation data of ground meteorological variables from multiple ground meteorological stations; Obtaining large-scale atmospheric variables data from the global NCEP reanalysis dataset as initial observation data of large-scale atmospheric variables;
Obtaining initial simulation data of ground meteorological variables and large-scale atmospheric variables from each GCM during the same period of the initial large-scale atmospheric variables observation data;
Applying bilinear interpolation to match the spatial resolution of the initial ground meteorological variable simulation data to that of the initial ground meteorological variable observation data. Similarly, apply bilinear interpolation to match the spatial resolution of the initial large-scale atmospheric variables simulation data to that of the initial large-scale atmospheric variables observation data;
Performing arithmetic averaging or spatial interpolation on the already matched observation data of the initial ground meteorological variables and initial large-scale atmospheric variables to obtain the final observation data; performing arithmetic averaging or spatial interpolation on the already matched simulation data of the initial ground meteorological variable and initial large-scale atmospheric variables to obtain the final simulation data from GCMs.

8. A computer equipment comprise a memory, a processor and a computer program stored on the memory and capable of running on the processor. It is characterized in that the processor executes the above-mentioned computer program to implement the evaluation method for GCMs' simulation performance at the watershed scale as claimed in claim 1.

9. A computer-readable storage medium in which a computer program is stored, is characterized in that the computer program is executed by the processor to implement the evaluation method for GCMs' simulation performance at the watershed scale as claimed in claim 1.
